(19) United States
(12) Patent Application Publication
(10) Pub. No.: US 2012/0031489 A1
(43) Pub. Date: Feb. 9, 2012

(54) METHOD FOR PRODUCING A TEXTURED PLATE FOR A PHOTOVOLTAIC DEVICE

(75) Inventor: Ben Slager, Rhenen (NL)

(73) Assignee: SOLAR EXCEL B.V., Rhenen (NL)

(21) Appl. No.: 13/263,603

(22) PCT Filed: Apr. 8, 2010
(86) PCT No.: PCT/EP10/54639

§ 371 Date: Oct. 7, 2011

(30) Foreign Application Priority Data
Apr. 8, 2009 (EP) 09157629.8
Jun. 5, 2009 (EP) 09162036.9

(51) Int. Cl. H01L 31/0232; B29C 59/02

(52) U.S. Cl. 136/259; 264/293

(57) ABSTRACT

A method for producing a polymeric cover plate with a surface relief texture, whereby the at least one surface relief structure is made of structures, whereby each structure has a height of at least 0.5 mm, the method including thermally softening a polymer, bringing the softened polymer via pressure into contact with a mold which contains an inverse image of the desired surface relief texture, and hardening the softened polymer, while maintaining the pressure between the polymer and the mold.

### TECHNICAL FIELD

The invention pertains to a method for producing a polymeric cover plate.

The obtained polymeric cover plate can be used directly as a cover plate for a photovoltaic device or is applied to one of the surfaces of a transparent substrate by using an appropriate adhesive. The transparent substrate containing one or more polymeric cover plates can be used as or on top of another cover plate for a photovoltaic device.

### BACKGROUND

Solar cells (photovoltaic cells or photovoltaic devices) are commonly used to convert light energy into electrical energy. This effect is known as the photovoltaic effect. Solar cells contain an active layer which consists of a light absorbing material which generates charge carriers upon light exposure. An active layer which is commonly used in photovoltaic devices is silicon. However, a variety of materials can be encountered like for example gallium arsenide (GaAs), cadmium telluride (CdTe) or copper indium gallium diselenide (CICS). The charges, which are generated in the active layer, are separated to conductive contacts that transmit electricity. Due to the thin and brittle nature of the active layer it is usually protected from external influences by a transparent cover plate (commonly glass). This cover plate is positioned between the light source and the light receiving side of the active layer. Most of the time, a single solar cell cannot produce enough electricity for the desired purpose and the cells are therefore linked together to form a larger type of photovoltaic device. Assemblies of cells are used to make solar modules, which in turn may be linked into photovoltaic arrays. Individual cells can be used to power small devices such as calculators or electronic watches. Modules or photovoltaic arrays are for example encountered on the rooftops of houses or off-grid applications such as boats, traffic signs or spacecrafts.

It is known from the art that both the active layer and the cover plate reflect a part of the light incident to the photovoltaic device. Especially the high refractive index of the active layer causes large reflection losses which can, in the case of silicon, be over 30% of the incident light. Since the reflected light cannot be converted into electrical energy these reflection losses cause a large reduction in the efficiency of a photovoltaic device.

It is known from the art that the reflection losses of a photovoltaic device can be reduced by applying a surface texture to the cover plate. The surface texture reduces the reflection losses of the active layer (which is known as “trapping”) and of the cover plate (which is known as “antireflection”). The size of said surface textures are always in the millimetre range since sufficient strength is required to ensure long-term outdoor durability. Smaller structures would be more susceptible to damaging while larger structures would require too much material and thus result in high product costs. Different surface textures can be used such as for example an array of pyramidal textures (WO03/046617), V-shaped grooves (G. A. Landis, 21^{st} IEEE photovoltaic specialist conference, 1304-1307 (1990)), round pits (P. Sanchez-Friera, IEEE 4^{th} World Conference on photovoltaic energy conversion, 2156-2159 (2006)), or structures consisting of a base and an apex which are connected by n-polygonal surfaces with n being equal to 4 or higher (WO2009059998) are applied to a cover plate to reduce the reflection losses of said plate and increase the transmission of light. These cover plates can increase the efficiency of the photovoltaic device by up to 6% according to a model study (U. Blieske et al., 3rd World Conference on Photovoltaic Energy Conversion, 188-191 (2003)).

In practice the results are however less than 6% and usually an improvement no more than 3% is obtained. This low performance can be attributed to the manufacturing process. The surface textures are commonly applied to the glass or polymeric cover plate via hot rolling (WO2005111670, WO03/046617). This is a typical technique for creating millimetre sized structures in fast production process. With these techniques the material to be textured is softened by heating. The softened material is textured by mechanical contact with the hard (usually metal) mold. To fix the texture, the material it is cooled to room temperature at which it hardens. The problem arises from that both polymers and glasses have the tendency to deform back to their untextured flat shape. This relaxation is caused by the viscoelastic behaviour of polymers and glasses. During hot rolling the material leaves the mold when it is still soft and thus deforms resulting in an imperfect replication of the relief in the mold. As a result the final shape of the texture on the cover plate is deformed from its ideal shape. The performance increase of photovoltaic devices by the imperfectly textured cover plate is of course lower than from a perfectly textured cover plate.

It is suggested in WO03/046617 to use the techniques of thermoforming or casting. These techniques are however far from ideal. With thermoforming a polymer sheet/plate is softened by heating. The softened plate/sheet is fully deformed over its complete thickness by placing it into contact with mold. This, while a deformation at the surface of the polymeric plate is required for creating a surface relief textured. Thermoforming is therefore almost exclusively used for creating three dimension objects such as boxes or cups, but not to texture the surface of a polymeric plate. Although casting can be used to create a surface relief texture it is usually used for metals or glasses but not for polymers. Casting should be understood as a manufacturing process by which a liquid material is usually poured into a mold, which contains a hollow cavity of the desired shape, and then allowed to solidify. Casting materials are usually metals or various cold setting materials that cure after mixing two or more components together; examples are epoxy, concrete, plaster and clay. The absence of a pressure during hardening of the liquefied material in the casting process upon cooling results in deformation due to thermal shrinkage. Also the processing speed is slow since casting is done at atmospheric pressure. Another casting technique is resin casting. Resin casting is a method of plastic casting here a mold is filled with a liquid synthetic resin which then hardens. Most commonly a thermosetting resin is used that polymerizes by mixing with a curing agent at room temperature and normal pressure. The synthetic resins used include polyurethane resin, epoxy resin, unsaturated polyester resin and silicone resin. As already described the absence of a pressure during the hardening results in a deformation and a thermal shrinkage.

EP 1 054 456 discloses a method for producing a protective sheet, whereby a thermoplastic resin layer is heated and an embossing is pressed against the softened thermoplastic resin layer. Structures with a high reproducibility cannot be produced via this method, because such structures will lose the form while hardening. As a result a plurality of individual structures occurs by using this method.

It is known from DE 100 01 135 to create a surface texturing with structures in the range of pm to nm. Contactless hardening is a main point in the method described in DE 100 01 135.

Furthermore, from WO 2008/145176 a method for producing micro-lenses is known. In this method a thermoplastic polymer is hot embossed with a stamp. By the method disclosed in the prior art document it is possible to create very small structures in the range of pm. Structures, larger than micro-lenses cannot be produced by this method.

It is the objective of the invention to overcome the problems of the prior art.

### SUMMARY

The problems discussed above can be overcome by a method for producing a polymeric cover plate for a photovoltaic device which exhibits at least one surface relief texture, whereby the at least one surface relief structure is made of structures, whereby each structure has a height of at least 0.5 mm, the method comprising: thermally softening a polymer; bringing the softened polymer via pressure into contact with a mold which contains an inverse image of the desired surface relief texture; and hardening said softened polymer, while maintaining the pressure between the polymer and the mold.

The polymeric cover plate can also be called a surface textured polymeric plate.

The surface relief texture is made of structures, whereby each structure has a height between 0.5 to 10 mm, more preferably between 0.75 to 5 mm and most preferably between 0.95 to 4 mm. It should be noted that a method for producing structures in this ranges is totally different to a method for producing large structures. For producing structures in the mentioned range the requirements regarding accurateness and defect frequency are totally different to methods for producing large structures. Therefore, the method described in U.S. Pat. No. 6,075,652 is not comparable with the present invention.

None of the known processing techniques are suitable for creating millimeter sized structures with micrometer precision over large surfaces. This precision is required to ensure the performance of the device. The main problems are deformation of relief structures if made of millimetre size or deformation of the devices themselves. It is known from the prior art that it is possible to create micrometer structures with micrometer precision over large surfaces.

By using the method according to the invention, a surface textured cover plate can be obtained of superior quality and performance compared to the known methods. The relief on the obtained polymeric plate is an accurate negative copy of the relief inside the mold. A plate manufactured according to the method described in this invention can increase the performance of the photovoltaic device.

### DETAILED DESCRIPTION

The obtained surface textured polymeric plate can preferably be used directly as a cover plate for a photovoltaic device or is used on top of a cover plate for a photovoltaic device. In this last ease the surface textured polymeric plate is preferably coated with an additional layer after hardening the polymeric plate. In one embodiment the surface textured polymeric plate is for example applied to one of the surfaces of a transparent substrate by using an appropriate adhesive. The transparent substrate containing one or more surface textured polymeric plates can be used as or on top of a cover plate for a photovoltaic device.

A cover plate for a photovoltaic device is any plate which can be used in combination with photovoltaic device. Preferably said plate is positioned in front of the light receiving side of the photovoltaic device and most preferably in direct optical contact (i.e. no air gap) with the light receiving side of the active layer in the photovoltaic device.

The cover plate can be any size, but preferably its lateral dimensions (x,y) are significantly large than its axial dimensions (z).

Preferably, a mold with an inverse structure of pyramids and/or grooves and/or hemispheres and/or cubicals is used for producing the structures for the surface textured polymeric plate.

Depending on the applied mold, the surface textured polymeric plate can exhibit a groove, pyramid, cone and/or hemisphere structure and/or structures known from published application WO 2009/059998, whereby the published application is filed in the name of the applicant and is hereby incorporated by reference in its entirety. The surface texture of the cover plate can be any texture in relief at the surface of a plate. The texture can consist of a single kind of structure or a plurality of varied structures. The structures can be positioned in an ordered array or a random orientation. The texture (this means the surface texture) can be positioned on one or more of the surfaces of the plate and preferably the texture is positioned on the surface of the cover plate which faces away from the active layer of the photovoltaic device. When describing the projected area of a structure by a circle wherein at least one of the edges of the projected area lie on the circumferential line of the circle, the diameter “D” of the circle is preferably less than 30 mm, more preferably less than 10 mm and most preferably less than 3 mm.

In the following the structure is specified, whereby the specification is applied to a single structure. Certainly the specification is also applied to a plurality of structures.

Preferably, the structure contains three square (this means “n” polygonal) surfaces (n=4) which directly connect a hexagonal base to a single apex and the structure contains 9 surfaces in total. It is also possible that the structure exhibits partially rounded surfaces. A rounded, curved or partially curved surface is an n-polygonal surface where “n” is infinite.

It is also preferred when the structure comprises a m-polygonal base and an apex area. Said m-polygonal base and said apex area are connected by “m” surfaces with “m” being equal to 3 or higher. The structure is preferably further characterized in that at most two of the “m” surfaces, which connect the apex to the base should be n-polygonal shaped with “n” being equal to four or higher. The apex area is defined as the upper part of an individual geometrical optical structure to which the surfaces which are connected to the base combine. The apex area can be a point (e.g. as encountered in a pyramid or cone) or a line (e.g. as encountered in a groove). Examples of a single structure of the array of geometrical optical structures are pyramids with a rectangular base, cones, v-shaped grooves, tilted V-grooves or a sawtooth profile.

In a preferred embodiment of the invention “m” is extremely large and be considered as being equal to infinite. In this particular case an individual geometrical optical structure of the array exhibits an at least partially rounded cross section. Such a geometrical optical structure may be in the shape of a cone.

The apex area may also be a surface which is parallel to the m-polygonal base of the individual geometrical optical structure. Examples of such a single structure of the array of geometrical optical structures are cylinders with a circular cross section or cupola shaped structures.

In one preferred embodiment of the invention the surface relief textured cover plate mentioned in WO2009059998 should be produced such that the orientation of a single relief texture whereby one of the three n-polygonal surfaces of that the single relief texture comprises is parallel to one of the outer edges of the surface relief textured plate. Preferably, the n-polygonal surface should be positioned parallel to the lower or upper outer edge of the relief textured plate. Orienting the relief texture has advantages for processing and self-cleaning properties. This effect is already described in US20070240754A1 for pyramid shaped structures. Surprisingly for pyramid shaped structures this effect is, however, achieved by placing the triangular surfaces that the pyramid comprises not parallel to one of outer edges of the surface relief textured plate.

In a preferred embodiment the relief texture (this means the structures) of the textured plate is covered with an additional coating with a different refraction index than the material in which the relief structures are created. The shape of the coating is complementary to the structures such that the surface of the coating which is not in contact with structures, can be considered as flat. For example, it is possible to create a textured plate with structures in a high refractive index material and coat it with a low refractive index material such that there is no relief texture after coating. In other words, the high refractive relief structures are “filled” with low refractive index material.

Preferably, the surface textured polymeric plate is made by poly(ethylene), poly(propylene), poly(methylmethacrylate), poly(methylacrylate), polycarbonate, polyurethane, nylon 4,6, nylon 6,6, poly(vinylchloride) and/or poly(tetrafluoroethylene) or mixtures of these polymers. Also additives might be added to the polymer for processing, stabilization, additional functionalities or durability. Examples of such additives are inorganic (e.g. SiO₂ or TiO₂) nanoparticles, dyes, UV absorbers, MALS stabilizers, plasticizers, optical brighteners, inhibitors or anti oxidants.

The transparent substrate on which the surface textured polymeric plate can be applied can be polymeric or glass. The thickness of the substrate is preferably less than 10 cm, more preferable less than 1 cm most preferably less than 5 mm.

The transparent substrate may contain one surface textured polymeric plate, but preferably more than one textured polymeric plates and most preferably more than two textured polymeric plates.

The textured polymeric plate can be applied to the transparent substrate by using an appropriate adhesive. Such an adhesive should have a refractive index between 1.3 and 1.7 such that optical contact between the textured and transparent plate is obtained. The refractive index should be determined with an Abbe refractometer. The adhesive may comprise of a monomer, polymer, initiator, catalyst or any combination thereof. The polymer might also be textured while applied on top of the transparent substrate. In this case the adhesive might be the polymer itself preferably with additives in the polymer to promote adhesion (e.g. acid, amide, silanol, alcohol groups) or an adhesion promoter such as a thin coating of silanes which is applied to surface of the transparent substrate prior to applying the liquid polymer.

The mold containing the inverse of the desired relief texture can be made of any material. Examples of materials are polymeric (e.g. poly(ethylene), poly(propylene), poly(etheretherketone) or metallic (e.g. iron, nickel, steel or copper) or ceramic (e.g. glass or porcelain).

To create a surface relief texture in the polymer, for producing the surface textured polymeric plate, the polymer needs to be thermally softened. Preferably this can be done by heating the polymer to above its glass transition temperature or more preferably above the melting temperature. Preferably, the polymer is softened by heating the polymer into a liquid state and/or by heating the polymer into a rubbery state. It is also possible to heat parts of the polymer into a liquid state and parts of the polymer into a rubbery state. Such a variation in the softening process could be needful to create different deep structures into the surface textures polymeric plate.

Preferably, the polymer is hardened by cooling the polymer while maintaining the pressure between the polymer and the mold. This means, the polymer is hardening while maintaining the mold and the polymer in contact with each other. It is therefore hardly possible that the structure in the polymer material, generated by the mold, deforms during the hardening step. Due to this, the structure of the surface textured polymeric plate matches the inverse structure of the mold after hardening, with high accuracy. The reproducibility of the structure of the surface textured polymeric plate is therefore especially high.

Preferably, the cooling occurs in a temperature range of 20° C. to 150° C. More preferred the temperature for the cooling is in the range of 30° C. to 80° C., most preferred in the range of 35° C. to 50° C.

The softened polymer is brought in contact with the mold via pressure. Preferably, the pressure is in the range of 0.01 bar to 2000 bar. More preferred the pressure is in the range of 0.05 bar to 200 bar, and most preferred in the range of 0.1 bar to 50 bar. Preferably, the pressure can be applied to the softened polymer by for example liquefying said polymer and injecting said liquid polymer into a closed mold. In another preferred embodiment the pressure is applied to the polymer via the mold by for example softening said polymer and pressing the mold into said softened polymer.

Preferably, the method for producing a surface textured polymeric plate is a batch process.

Additionally, the invention pertains to a photovoltaic device containing a surface textured polymeric plate obtained by a method according to the invention.

Preferably, the textured polymeric plate is used as cover plate for the photovoltaic device. Alternatively or additionally the textured polymeric plate is used on the top of another cover plate of the photovoltaic device. For example the textured polymeric plate can be applied to the glass cover plate of a solar module.

To elucidate, but not to limit the invention, the following examples are provided:

### Example 1

Thermally liquefied polymethylmethacrylate (PMMA) is injected into a closed nickel mold (33×33×0.15 cm) containing an array of square based pyramid structures with a height of 1 mm. The liquefied polymer is hardened by cooling to approximately 40 degrees Celsius. After hardening the mold is opened and a textured polymeric plate is obtained. A total of four of the textured plates are applied to a glass plate (substrate) of 1×1 meter by using liquid adhesive. The glass plate containing the textured plates is used as a cover plate for a photovoltaic device.

### Example 2

A plate 33×33×0.15 cm of polymethylmethacrylate (PMMA) is thermally softened by raising its temperature homogenously to approximately 135 degrees Celsius which makes the material rubbery. A nickel mold of the same size is pressed into the softened PMMA by using a pressure of 150 bar. The mold contains an array of square based pyramid structures with a height of 1 mm. The softened plate of PMMA is hardened by cooling to approximately 40 degrees Celsius while maintaining pressure of the nickel mold on the plate. After hardening the mold is opened and a textured polymeric plate is obtained. A total of four of the textured plates are applied to a glass plate (substrate) of 1×1 meter by using liquid adhesive with a refractive index (after hardening) of approximately 1.5. The glass plate containing the textured plates is used as a cover plate for a photovoltaic device.

1. A method for producing a polymeric cover plate for a photovoltaic device which exhibits at least one surface relief texture, whereby the at least one surface relief structure is made of structures, whereby each structure has a height of at least 0.5 mm, the method comprising:
thermally softening a polymer;
bringing the softened polymer via pressure into contact with a mold which contains an inverse image of the desired surface relief texture: and
hardening said softened polymer, while maintaining the pressure between the polymer and the mold.

2. The method according to claim 1, wherein the polymer is hardened by cooling the polymer.

3. The method according to claim 2, wherein the cooling occurs in a temperature range of 20° C. to 150° C.

4. The method according to claim 1, wherein the polymer is softened by heating the polymer into a liquid state or by heating the polymer into a rubbery state.

5. The method according to claim 1, wherein the pressure is in the range of 0.1 bar to 2000 bar.

6. The method according to claim 1, wherein the polymer is polymethylmethacrylate.

7. The method according to claim 1, wherein the mold has an inverse structure of pyramids and/or grooves and/or hemispheres and/or cubicals.

8. The method according to claim 1, wherein the polymeric plate is coated with an additional layer after hardening the polymeric plate.

9. The method according to claim 1, wherein the method for producing is a batch process.

10. A photovoltaic device comprising a polymeric plate obtained by a method according to claim 1.

11. A photovoltaic device according to claim 10, wherein the polymeric plate is textured and used as a cover plate.

12. A photovoltaic device according to claim 10, wherein the polymeric plate is textured and used on top of a first cover plate.
